(19) United States
(12) Patent Application Publication
(10) Pub. No.: US 2026/0222062 A1
(43) Pub. Date: Jul. 30, 2026

(54) ESTIMATION APPARATUS, FILTER GENERATION APPARATUS, ESTIMATION METHOD AND FILTER GENERATION METHOD

(71) Applicant: NIPPON TELEGRAPH AND TELEPHONE CORPORATION, Tokyo (JP)

(72) Inventors: Ryo IGARASHI, Musashino-shi (JP); Junichi KANI, Musashino-shi (JP); Kazutaka HARA, Musashino-shi (JP); Ryo KOMA, Musashino-shi (JP)

(73) Assignee: NIPPON TELEGRAPH AND TELEPHONE CORPORATION, Tokyo (JP)

(21) Appl. No.: 19/146,274

(22) PCT Filed: Jan. 11, 2023
(86) PCT No.: PCT/JP2023/000415

§ 371 Date: Jul. 8, 2025

(51) Int. Cl. H04B 10/079; G01R 29/08

(52) U.S. Cl. CPC H04B 10/07953; G01R 29/0814

(57) ABSTRACT

An estimation device includes: an electric field estimation unit that estimates a simulation signal of an output electric field waveform at an output terminal of a transmission line by using a filter of a tap coefficient generated for each combination of a light intensity of a first input electric field waveform at an input terminal of the transmission line and a transmission distance on the basis of the first input electric field waveform and the output electric field waveform and a generated second input electric field waveform; and an error rate estimation unit that estimates an error rate of a code sequence at the output terminal of the transmission line on the basis of the simulation signal of the output electric field waveform. A filter generation device includes a filter unit that generates a tap coefficient of a filter for each combination of a light intensity of an input electric field waveform at an input terminal of a transmission line and a transmission distance so as to reduce a difference between a shape of a first output electric field waveform at an output terminal of the transmission line and a shape of a second output electric field waveform output from the filter.

### TECHNICAL FIELD

The present invention relates to an estimation device, a filter generation device, an estimation method, and a filter generation method.

### BACKGROUND ART

In an optical communication system using a reconfigurable optical add/drop multiplexer (ROADM) (see Non Patent Literature 1), each node of a transmission line transfers an optical signal transmitted from a first communication device to a second communication device by using an optical path. In the All-Photonics Network (APN), an optical path is connected end to end without performing photoelectric conversion on an optical signal.

FIG. 11 shows a configuration example of an optical communication system. The optical communication system of FIG. 11 includes a first communication device, a second communication device, and a transmission line. The transmission line of FIG. 11 includes a first node, a second node, a third node, a fourth node, and a fifth node. Each node includes an optical switch (not shown).

Each node transfers an optical signal without performing photoelectric conversion on the optical signal. Thus, an optical signal transmitted from the first communication device is transferred to the second communication device in the form of light (electric field waveform).

In the All-Photonics Network, in a case where a signal for requesting connection to the second communication device is transmitted from the first communication device, an appropriate optical path from the first communication device to the second communication device is selected from among a plurality of optical paths in the transmission line.

Here, a modulation method of the optical signal, a transmission rate, a transmission distance (the length of the transmission line), the type of optical fiber of the transmission line, a gain of an optical amplifier through which the optical signal is transmitted, and the like are different for each optical path, and thus a bit error rate in the second communication device is different for each optical path. This makes it necessary to select an optical path capable of performing error-free transmission (an optical path having a bit error rate less than a predetermined value) from among the plurality of optical paths.

The optical path may be selected on the basis of a result of confirming whether or not transmission is error-free for each optical path by actually transmitting an optical signal to each optical path. However, in this case, it takes time to make confirmation on all the plurality of optical paths, and thus a huge amount of time is required to open an optical path. Therefore, in order to open an optical path in a short time, it is effective to select an optical path capable of performing error-free transmission on the basis of a bit error rate estimated in advance for each optical path.

As a method of estimating a bit error rate in an optical communication system, there is a method in which an estimation device estimates a bit error rate by propagation simulation. For example, the estimation device estimates an electric field waveform of an optical signal transmitted through the transmission line including an optical fiber by propagation simulation. The estimation device simulates the electric field waveform in the second communication device by adding appropriate noise to the electric field waveform. The estimation device performs threshold determination processing on a simulation result to identify a code sequence (received code sequence) received by the second communication device. The estimation device estimates a bit error rate on the basis of a difference between the identified received code sequence and a code sequence (transmitted code sequence) transmitted from the first communication device.

The estimation device accurately estimates a change in the electric field waveform of the optical signal transmitted through the transmission line by performing predetermined algorithm processing (e.g. split step Fourier method (SSFM)) on the nonlinear Schrödinger equation. In this case, the estimation device estimates the electric field waveform (simulation signal) in which a linear change (wavelength dispersion) and a nonlinear change (self-phase modulation) have occurred due to the transmission. Therefore, even in a case where nonlinear waveform distortion occurs in the electric field waveform, it is possible to accurately estimate a change in the electric field waveform of the optical signal transmitted through the transmission line.

However, in the method based on the split step Fourier method, a fiber section in which an optical signal is transmitted is divided, and calculation of the electric field waveform in each divided fiber section is sequentially repeated. Thus, a calculation time increases as a transmission distance increases. This makes it difficult to apply this estimation method to the All-Photonics Network in which real-time operation is required.

In order to solve such a problem, “GNPy” is provided as a method of estimating a bit error rate in a short time (see Non Patent Literature 2). In “GNPy”, it is possible to estimate a nonlinear change in a short time by approximating the nonlinear change by random Gaussian noise (see Non Patent Literatures 3 and 4).

### CITATION LIST

### Non Patent Literature

Non Patent Literature 1: M. Birk et al., “The OpenROADM initiative [Invited]”, Journal of Optical Communications and Networking, vol. 12, no. 6, pp. C58-67, June 2020.
Non Patent Literature 2: A. Ferrari et al., “GNPy: an open source application for physical layer aware open optical networks”, Journal of Optical Communications and Networking, vol. 12, no. 6, pp. C31-C40, June 2020.
Non Patent Literature 3: P. Poggiolini et al., “A Detailed Analytical Derivation of the GN Model of Non-Linear Interference in Coherent Optical Transmission Systems”
Non Patent Literature 4: P. Poggiolini et al., “The GN Model of Non-Linear Propagation in Uncompensated Coherent Optical Systems”, Journal of Lightwave Technology, vol. 30, no. 24, pp. 3857-3879 DECEMBER 2012.

### SUMMARY OF INVENTION

### Technical Problem

However, Gaussian noise approximation of a nonlinear change holds only in a case where a transmission distance of an optical signal is a predetermined distance or more. Thus, in a case where the transmission distance of the optical signal is less than the predetermined distance, the Gaussian noise approximation of the nonlinear change cannot be applied. Therefore, for example, the Gaussian noise approximation of the nonlinear change cannot be applied to communication in a data center in which a transmission distance of an optical signal is relatively short.

As described above, there is a problem that, in a case where the transmission distance of the optical signal is less than the predetermined distance, a bit error rate cannot be estimated in a short time on the basis of a nonlinearly changed electric field waveform.

In view of the above circumstances, an object of the present invention is to provide an estimation device, a filter generation device, an estimation method, and a filter generation method capable of improving accuracy of estimating a bit error rate in a short time on the basis of a nonlinearly changed electric field waveform even in a case where a transmission distance of an optical signal is less than a predetermined distance.

### Solution to Problem

An aspect of the present invention is an estimation device including: an electric field estimation unit that estimates a simulation signal of an output electric field waveform at an output terminal of a transmission line by using a filter of a tap coefficient generated for each combination of a light intensity of a first input electric field waveform at an input terminal of the transmission line and a transmission distance on the basis of the first input electric field waveform and the output electric field waveform and a generated second input electric field waveform; and an error rate estimation unit that estimates an error rate of a code sequence at the output terminal of the transmission line on the basis of the simulation signal of the output electric field waveform.

An aspect of the present invention is a filter generation device including a filter unit that generates a tap coefficient of a second filter for each combination of a light intensity of an input electric field waveform at an input terminal of a transmission line and a transmission distance so as to reduce a difference between a shape of a first output electric field waveform at an output terminal of the transmission line and a shape of a second output electric field waveform output from a first filter.

An aspect of the present invention is an estimation method performed by an estimation device, the estimation method including: a step of estimating a simulation signal of an output electric field waveform at an output terminal of a transmission line by using a filter of a tap coefficient generated for each combination of a light intensity of a first input electric field waveform at an input terminal of the transmission line and a transmission distance on the basis of the first input electric field waveform and the output electric field waveform and a generated second input electric field waveform; and a step of estimating an error rate of a code sequence at the output terminal of the transmission line on the basis of the simulation signal of the output electric field waveform.

An aspect of the present invention is a filter generation method performed by a filter generation device, the filter generation method including a step of generating a tap coefficient of a filter for each combination of a light intensity of an input electric field waveform at an input terminal of a transmission line and a transmission distance so as to reduce a difference between a shape of a first output electric field waveform at an output terminal of the transmission line and a shape of a second output electric field waveform output from the filter.

### Advantageous Effects of Invention

According to the present invention, even in a case where a transmission distance of an optical signal is less than a predetermined distance, it is possible to improve accuracy of estimating a bit error rate in a short time on the basis of a nonlinearly changed electric field waveform.

### BRIEF DESCRIPTION OF DRAWINGS

FIG. 1 shows a configuration example of an estimation system in a first embodiment.

FIG. 2 shows a configuration example of an optical communication system in the first embodiment.

FIG. 3 shows a configuration example of a filter generation device in the first embodiment.

FIG. 4 shows an example of a lookup table in the first embodiment.

FIG. 5 is a flowchart showing an operation example of an estimation device in the first embodiment.

FIG. 6 shows a configuration example of an estimation system in a second embodiment.

FIG. 7 shows a configuration example of a filter generation device in the second embodiment.

FIG. 8 shows a configuration example of an estimation system in a third embodiment.

FIG. 9 shows a configuration example of a filter generation device in the third embodiment.

FIG. 10 shows a hardware configuration example of the estimation system in each embodiment.

FIG. 11 shows a configuration example of an optical communication system.

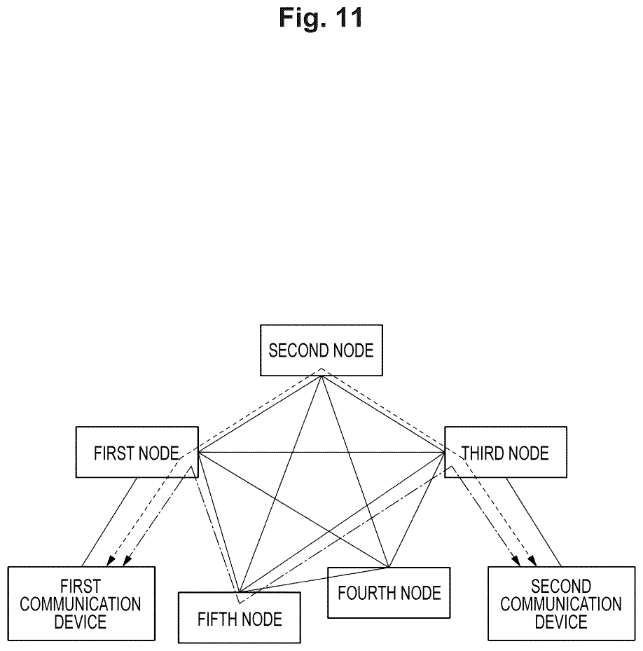

### DESCRIPTION OF EMBODIMENTS

Embodiments of the present invention will be described in detail with reference to the drawings.

### First Embodiment

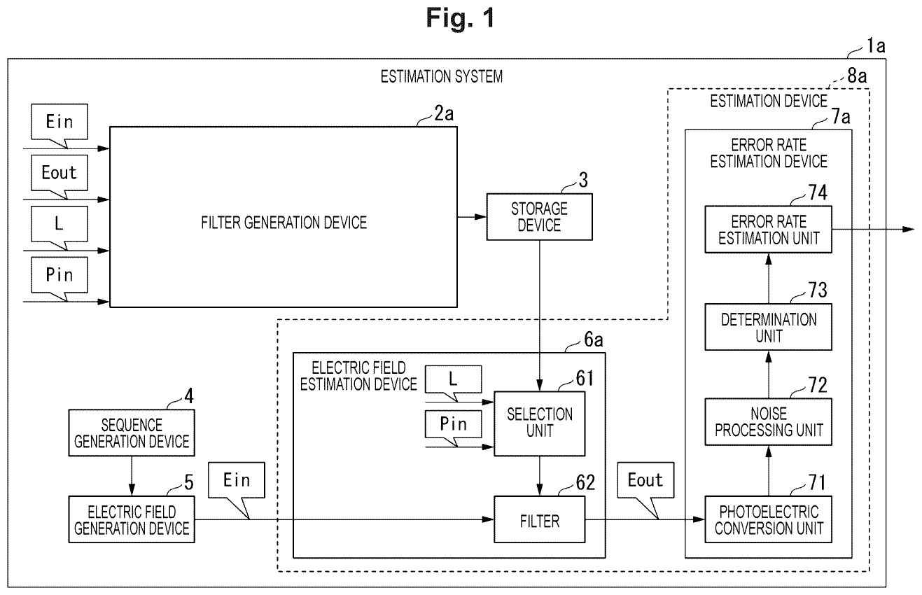

FIG. 1 shows a configuration example of an estimation system 1a in a first embodiment. The estimation system 1a is a system that estimates a bit error rate according to a change in an electric field waveform of an optical signal transmitted through a transmission line of an optical communication system in real time (within a predetermined delay time). That is, the estimation system 1a is a system that calculates an electric field waveform at the time of arrival at a second communication device on the basis of an optical signal corresponding to a transmitted code sequence transmitted from a first communication device and estimates a bit error rate in the second communication device in real time on the basis of the calculated electric field waveform.

Here, when the optical signal (input optical signal) corresponding to the transmitted code sequence is transmitted to the transmission line, waveform distortion (linear waveform distortion and nonlinear waveform distortion) occurs in an input optical signal waveform in the transmission line due to an influence of a linear change and a nonlinear change caused by propagation. An output optical signal (hereinafter, referred to as an “output electric field waveform”) including this waveform distortion is output from an output terminal of the transmission line to a reception-side communication device. An influence of self-phase modulation, which is one of nonlinear changes, is uniquely determined according to a plurality of predetermined parameters. The plurality of predetermined parameters are, for example, the following three types of parameters: an electric field waveform of an optical signal (main signal) input to the transmission line; an intensity (light intensity) thereof; and a transmission distance of the optical signal. The linear change is, for example, a change caused by wavelength dispersion.

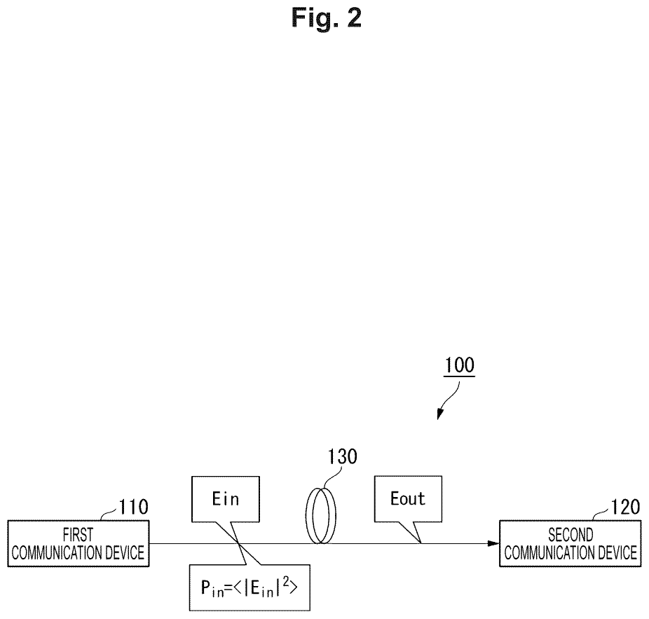

FIG. 2 shows a configuration example of an optical communication system 100 in the first embodiment. The optical communication system 100 is a system that performs communication by using an optical signal. The optical communication system 100 includes one or more first communication devices 110, a second communication device 120, and a transmission line 130.

Hereinafter, an electric field waveform of an optical signal at an input terminal of the transmission line or the like will be referred to as an “input electric field waveform”. The symbol “Eᵢₙ” denotes the input electric field waveform. The symbol “Eₒᵤₜ” denotes the output electric field waveform. Both the input electric field waveform “Eᵢₙ” and the output electric field waveform “Eₒᵤₜ” are time waveforms. The symbol “Pᵢₙ” denotes a time average “< >” of a light intensity “|Eᵢₙ|²” of the input electric field waveform.

The first communication device 110 (first user terminal) transmits an optical signal corresponding to a transmitted code sequence to the second communication device 120 (second user terminal) by using an optical path in the transmission line 130 (e.g. optical fiber) of a transmission distance “L”. Here, the input electric field waveform “Eᵢₙ” of the optical signal is input to the transmission line 130. The second communication device 120 (second user terminal) acquires the output electric field waveform “Eₒᵤₜ” linearly and nonlinearly changed in the transmission line 130.

The description of the configuration example of the estimation system 1a will be continued by referring back to FIG. 1.

The estimation system 1a includes a filter generation device 2a, a storage device 3, a sequence generation device 4, and an electric field generation device 5. The estimation system 1a includes an electric field estimation device 6a and an error rate estimation device 7a as an estimation device 8a. That is, the estimation device 8a includes the electric field estimation device 6a and the error rate estimation device 7a.

The electric field estimation device 6a (electric field estimation unit) includes a selection unit 61 and a filter 62. The error rate estimation device 7a includes a photoelectric conversion unit 71, a noise processing unit 72, a determination unit 73, and an error rate estimation unit 74.

At an estimation processing stage, the sequence generation device 4 generates in advance a transmitted code sequence to be transmitted from the first communication device 110 (transmission-side communication device) to the second communication device 120 (reception-side communication device). The sequence generation device 4 transmits the generated transmitted code sequence to the electric field generation device 5. The electric field generation device 5 generates the input electric field waveform “Eᵢₙ” of an optical signal corresponding to the transmitted code sequence on the basis of characteristics (e.g. a modulation method and a transmission characteristic) of the first communication device 110.

The estimation device 8a estimates a bit error rate in the second communication device 120 in real time on the basis of a difference between a received code sequence identified on the basis of the output electric field waveform “Eₒᵤₜ” and the transmitted code sequence transmitted from the first communication device 110. The electric field generation device 5 transmits the generated input electric field waveform “Eᵢₙ” to the electric field estimation device 6a. Here, the electric field estimation device 6a estimates the output electric field waveform “Eₒᵤₜ” by applying the filter 62 having a characteristic of the transmission line 130 to the input electric field waveform “Eᵢₙ”.

In the first embodiment, the selection unit 61 selects a tap coefficient of the filter corresponding to waveform characteristics of a linear change and a nonlinear change in a case where an optical signal is transmitted through the transmission line 130 (optical fiber) of the transmission distance “L” from among candidates for the tap coefficient registered in a lookup table stored in advance in the storage device 3 on the basis of the light intensity “Pᵢₙ=<|Eᵢₙ|²>” of the input electric field waveform at the input terminal of the transmission line 130 and the transmission distance “L”. The selection unit 61 sets the selected tap coefficient to the filter 62.

At a stage (lookup table generation stage) before the estimation processing stage, the filter generation device 2a (filter unit) generates a tap coefficient of the filter 62 for each combination of the transmission distance “L” and the light intensity “Pᵢₙ” of the input electric field waveform so as to reduce a difference between a shape of the output electric field waveform “Eₒᵤₜ” at the output terminal of the transmission line 130 and a shape of the output electric field waveform simulated by using the filter 62. The filter generation device 2a registers the generated tap coefficient in a lookup table. The storage device 3 stores the lookup table (tap coefficient of the filter 62) for each combination of the transmission distance “L” and the light intensity “Pᵢₙ” of the input electric field waveform.

The filter 62 is, for example, a Volterra filter (Reference Literature 1: N-P. Diamantopoulos et al., “On the Complexity Reduction of the Second-Order Volterra Nonlinear Equalizer for IM/DD Systems”, Journal of Lightwave Technology, vol. 37, no. 4, pp. 1214-1224 Feb. 15, 2019). The filter 62 may be, for example, a finite time impulse response filter (FIR filter) that is a first-order Volterra filter.

The filter 62 outputs the output electric field waveform “Eₒᵤₜ”, which has been influenced by the waveform characteristics of the linear change and the nonlinear change in a case where the input electric field waveform “Eᵢₙ” is transmitted through the transmission line 130 of the transmission distance “L”, to the error rate estimation device 7a.

The electric field estimation device 6a transmits the output electric field waveform “Eₒᵤₜ” to the error rate estimation device 7a. The photoelectric conversion unit 71 converts the output electric field waveform into an electric waveform. The photoelectric conversion unit 71 (detection unit) may be, for example, a direct-detection receiver (e.g. single photodiode) or a coherent receiver.

The noise processing unit 72 applies predetermined appropriate noise to an electrical signal. The predetermined appropriate noise is, for example, Gaussian noise (Reference Literature 2: W. Freude et al., “Quality Metrics for Optical Signals: Eye Diagram, Q-factor, OSNR, EVM and BER”, Mo.B1.5, ICTON 2012). The Gaussian noise may be, for example, thermal noise in the reception-side communication device and noise caused by amplified spontaneous emission (ASE).

The determination unit 73 performs threshold determination processing on the electrical signal to which the noise has been added, thereby identifying a received code sequence in the output electric field waveform received by the photoelectric conversion unit 71. The error rate estimation unit 74 estimates a bit error rate in the second communication device 120 on the basis of a difference between the identified received code sequence and the transmitted code sequence transmitted from the first communication device 110.

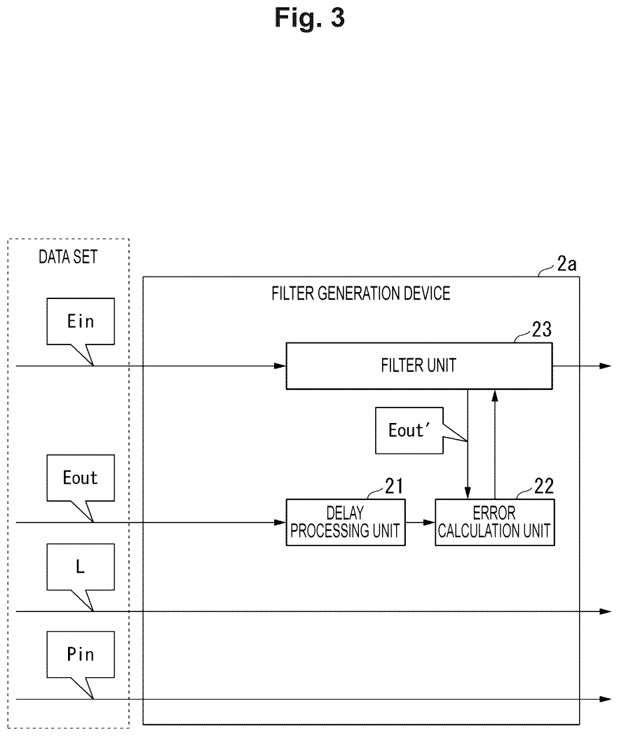

FIG. 3 shows a configuration example of the filter generation device 2a in the first embodiment. The filter generation device 2a includes a delay processing unit 21, an error calculation unit 22, and a filter unit 23.

The filter generation device 2a calculates an appropriate tap coefficient of the filter unit 23 as an appropriate tap coefficient of the filter 62 on the basis of a data set that is a combination of the light intensity “Pᵢₙ” of the input electric field waveform, the transmission distance “L”, the input electric field waveform “Eᵢₙ”, and the output electric field waveform “Eₒᵤₜ”. The filter unit 23 records the tap coefficient for the combination of the light intensity “Pᵢₙ” and the transmission distance “L” in the storage device 3 together with the light intensity “Pᵢₙ” and the transmission distance “L”. The delay processing unit 21 acquires the output electric field waveform “Eₒᵤₜ”. The output electric field waveform “Eₒᵤₜ” may be a waveform acquired in an actual experiment by the coherent receiver or a received power receiver (PR receiver) or a waveform calculated by using highly accurate waveform simulation. The highly accurate waveform simulation is, for example, waveform simulation using the split step Fourier method.

The delay processing unit 21 synchronizes the input electric field waveform “Eᵢₙ” with the output electric field waveform “Eₒᵤₜ” by giving a predetermined delay to the output electric field waveform “Eₒᵤₜ”. Meanwhile, the filter unit 23 outputs an output electric field waveform “Eₒᵤₜ′” generated by applying a predetermined transfer function to the input electric field waveform “Eᵢₙ” to the error calculation unit 22.

The error calculation unit 22 calculates an error “e=|Eₒᵤₜ−Eₒᵤₜ′|” of the shape of the output electric field waveform “Eₒᵤₜ′” with respect to the shape of the output electric field waveform “Eₒᵤₜ” output from the delay processing unit 21. The error calculation unit 22 feeds back the error “e” to the filter unit 23. The filter unit 23 updates the tap coefficient of the filter of the filter unit 23 by using a predetermined algorithm so as to satisfy the error “e=0”. The predetermined algorithm is, for example, a least mean square (LMS) algorithm.

Thus, the filter unit 23 generates a tap coefficient corresponding to the waveform characteristics of the linear change and the nonlinear change in the transmission line 130 for each combination of the light intensity “Pᵢₙ” of the input electric field waveform and the transmission distance “L”. In this manner, the filter unit 23 repeatedly performs calculation for the combination of the light intensity “Pᵢₙ” of the input electric field waveform and the transmission distance “L”. The filter unit 23 registers an appropriate tap coefficient in a lookup table for each combination of the light intensity “Pᵢₙ” and the transmission distance “L”.

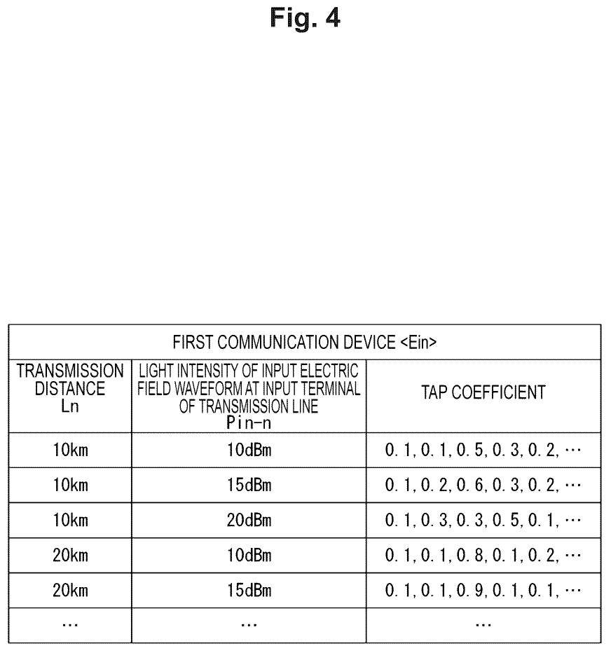

FIG. 4 shows an example of the lookup table in the first embodiment. At a stage before the estimation processing stage, a lookup table is generated for each input electric field waveform of an optical signal transmitted from the first communication device (transmission-side communication device). In the lookup table, the tap coefficient generated by the filter unit 23 is registered for each combination of a light intensity “Pᵢₙ₋ₙ” of the input electric field waveform and a transmission distance “Lₙ” (“n” is an index of the combination and is an integer of 1 or more).

Next, an operation example of the estimation device 8a will be described.

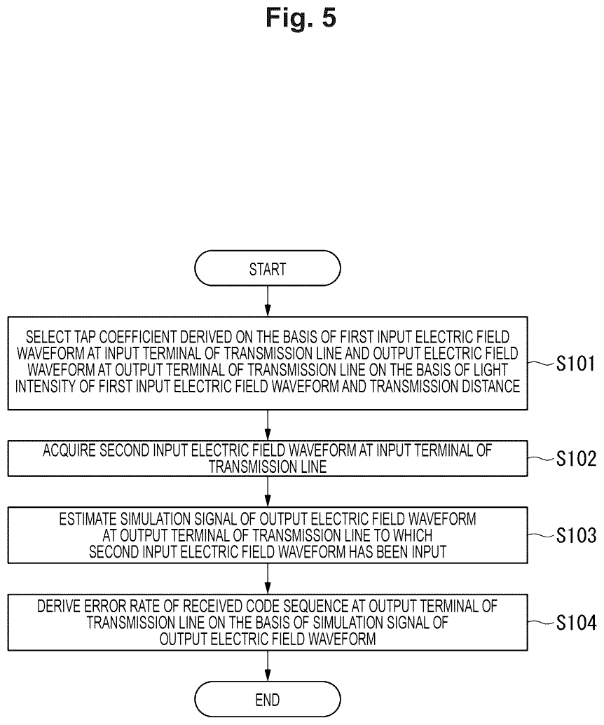

FIG. 5 is a flowchart showing an operation example of the estimation device 8a in the first embodiment. The selection unit 61 acquires a tap coefficient (lookup table) generated by the filter generation device 2a on the basis of the input electric field waveform “Eᵢₙ” at the input terminal of the transmission line 130, the light intensity “Pᵢₙ” of the input electric field waveform “Eᵢₙ”, the transmission distance “L”, and the output electric field waveform “Eₒᵤₜ” at the output terminal of the transmission line 130. The selection unit 61 selects a tap coefficient on the basis of the light intensity “Pᵢₙ” of the input electric field waveform and the transmission distance “L” (step S101).

The filter 62 to which the selected tap coefficient is set acquires the input electric field waveform “Eᵢₙ” at the input terminal of the transmission line 130 from the electric field generation device 5 (step S102). The filter 62 estimates a simulation signal “Eₒᵤₜ” of the output electric field waveform at the output terminal of the transmission line 130 to which the input electric field waveform “Eᵢₙ” has been input (step S103). The error rate estimation device 7a estimates an error rate of a received code sequence at the output terminal of the transmission line 130 (second communication device 120) on the basis of a result of comparison between a transmitted code sequence at the input terminal of the transmission line 130 (first communication device 110) and the simulation signal “Eₒᵤₜ” of the output electric field waveform (step S104).

As described above, the filter generation device 2a generates the tap coefficient of the filter unit 23 (filter) for each combination of the light intensity “Pᵢₙ” of the input electric field waveform at the input terminal of the transmission line 130 and the transmission distance “L” on the basis of the input electric field waveform “Eᵢₙ” (first input electric field waveform) at the input terminal of the transmission line 130 and the output electric field waveform “Eₒᵤₜ” (first output electric field waveform) at the output terminal of the transmission line 130. Here, the filter unit 23 generates the tap coefficient of the filter unit 23 (filter) as the tap coefficient of the filter 62 so as to reduce a difference between the shape of the output electric field waveform “Eₒᵤₜ” (first output electric field waveform) at the output terminal of the transmission line 130 and the shape of the output electric field waveform “Eₒᵤₜ′” (second output electric field waveform) output from the filter unit 23 (filter).

A tap coefficient selected from among the generated tap coefficients is set to the filter 62. The electric field estimation device 6a (electric field estimation unit) (electric field simulation unit) estimates the simulation signal “Eₒᵤₜ” of the output electric field waveform by using the filter 62 and the input electric field waveform “Eᵢₙ” (second input electric field waveform) generated by the electric field generation device 5. The error rate estimation device 7a (error rate estimation unit) estimates an error rate of the received code sequence at the output terminal of the transmission line 130 (second communication device 120) on the basis of the simulation signal “Eₒᵤₜ” of the output electric field waveform.

Thus, even in a case where a transmission distance of an optical signal is less than a predetermined distance, it is possible to improve accuracy of estimating a bit error rate in a short time on the basis of a nonlinearly changed electric field waveform. In the method based on the split step Fourier method, an amount of calculation required to estimate the bit error rate increases as the transmission distance increases. Meanwhile, in the estimation system 1a, even if the transmission distance increases, the amount of calculation required to estimate the bit error rate does not increase. This makes it possible to reduce a calculation time required to estimate the bit error rate.

### Second Embodiment

In a second embodiment, main differences from the first embodiment are as follows: an electric field estimation device includes a first linear change generation unit; and a filter generation device includes a second linear change generation unit. In the second embodiment, the differences from the first embodiment will be mainly described.

Of a linear change and a nonlinear change, the linear change can be calculated in a shorter time than the nonlinear change by solving a linear term of the nonlinear Schrödinger equation. Therefore, in the second embodiment, a linear change of an electric field waveform is generated at the preceding stage by a method based on the Schrödinger equation (the linear term of the nonlinear Schrödinger equation). At the subsequent stage, a filter 62 gives a characteristic of the nonlinear change (nonlinear deterioration) to the electric field waveform in which the linear change has been generated.

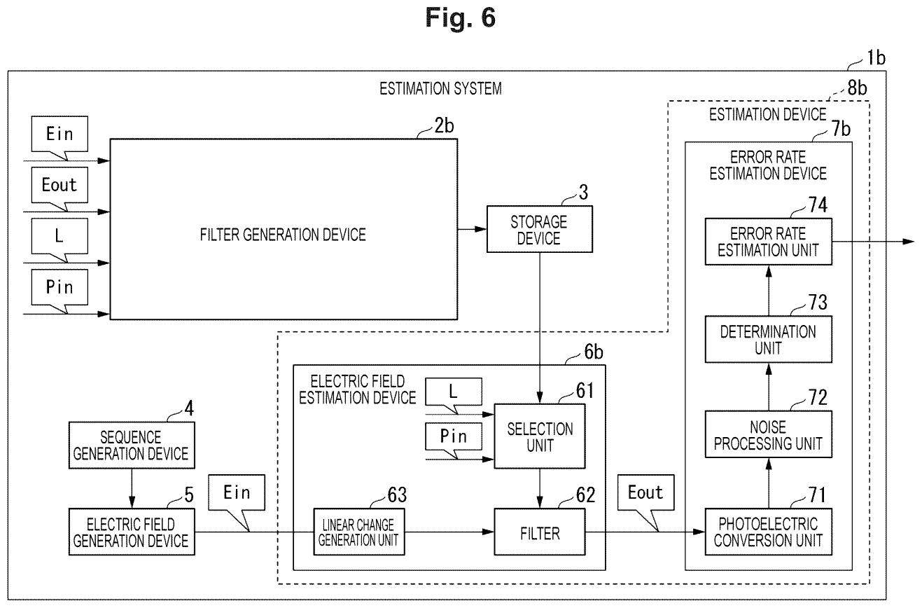

FIG. 6 shows a configuration example of an estimation system 1b in the second embodiment. The estimation system 1b includes a filter generation device 2b, the storage device 3, the sequence generation device 4, and the electric field generation device 5. The estimation system 1b includes an electric field estimation device 6b and an error rate estimation device 7b as an estimation device 8b.

The electric field estimation device 6b includes the selection unit 61, the filter 62, and a linear change generation unit 63. The error rate estimation device 7b includes the photoelectric conversion unit 71, the noise processing unit 72, the determination unit 73, and the error rate estimation unit 74.

At the estimation processing stage, the input electric field waveform “Eᵢₙ” is given to the linear change generation unit 63 (first linear change generation unit). The linear change generation unit 63 calculates a linear change of the input electric field waveform “Eᵢₙ” transmitted through an optical fiber by the transmission distance “L” by the method based on the Schrödinger equation in a shorter time than a calculation time of a nonlinear change of the input electric field waveform “Eᵢₙ”. That is, the linear change generation unit 63 solves the linear term of the nonlinear Schrödinger equation for the electric field waveform, thereby generating a linear change of the electric field waveform in a shorter time than a generation time of the nonlinear change of the electric field waveform. The linear change generation unit 63 may give only the linear change to the electric field waveform transmitted through the optical fiber and does not need to give the nonlinear change thereto. The linear change generation unit 63 outputs the input electric field waveform “Eᵢₙ” subjected to linear change processing to the filter 62.

At the estimation processing stage, the selection unit 61 sets, to the filter 62, a tap coefficient based on a characteristic of a nonlinear change in an electric field waveform of a transmitted optical signal. The filter 62 performs nonlinear change processing on the input electric field waveform “Eᵢₙ” subjected to the linear change processing by the linear change generation unit 63. Therefore, the filter 62 estimates a simulation signal of the output electric field waveform subjected to the nonlinear change processing. The filter 62 outputs the simulation signal of the output electric field waveform subjected to the nonlinear change processing to the photoelectric conversion unit 71.

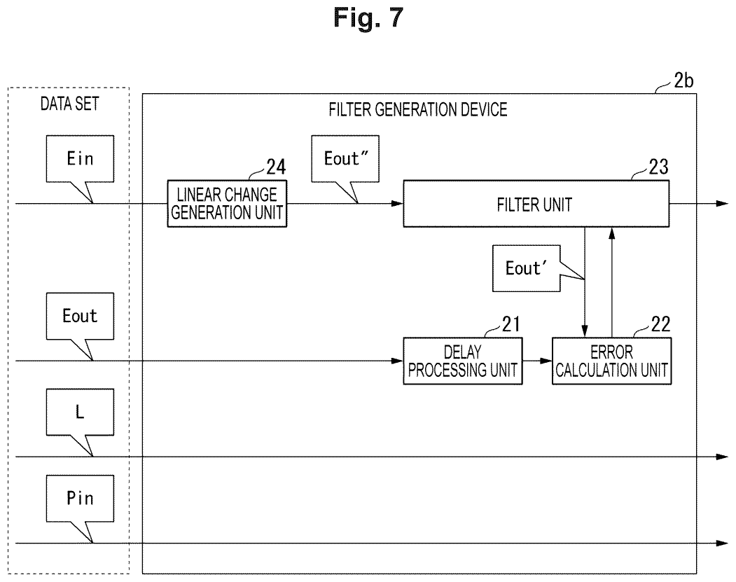

FIG. 7 shows a configuration example of the filter generation device 2b in the second embodiment. The filter generation device 2b includes the delay processing unit 21, the error calculation unit 22, the filter unit 23, and a linear change generation unit 24.

At a stage (lookup table generation stage) before the estimation processing stage, the input electric field waveform “Eᵢₙ” is given to the linear change generation unit 24 (second linear change generation unit). The linear change generation unit 24 calculates a linear change of the input electric field waveform “Eᵢₙ” transmitted through the optical fiber by the transmission distance “L” by the method based on the Schrödinger equation in a shorter time than the calculation time of the nonlinear change of the input electric field waveform “Eᵢₙ”. That is, the linear change generation unit 24 solves the linear term of the nonlinear Schrödinger equation for the electric field waveform, thereby generating the linear change of the electric field waveform in a shorter time than the generation time of the nonlinear change of the electric field waveform. The linear change generation unit 24 performs the linear change processing on the electric field waveform on the basis of a linear change generation result. The linear change generation unit 24 may give only the linear change to the electric field waveform transmitted through the optical fiber and does not need to give the nonlinear change thereto. The linear change generation unit 24 outputs an output electric field waveform “Eₒᵤₜ″” to the filter unit 23 as the input electric field waveform “Eᵢₙ” subjected to the linear change processing.

The filter unit 23 transmits the output electric field waveform “Eₒᵤₜ′” corresponding to the input electric field waveform “Eᵢₙ” to the error calculation unit 22. The error calculation unit 22 calculates the error “e” on the basis of “Eₒᵤₜ′” and “Eₒᵤₜ” from the delay processing unit. The error calculation unit 22 transmits the error “e” to the filter unit 23. The filter unit 23 minimizes the error “e” by updating the tap coefficient of the filter of the filter unit 23 by using an algorithm such as the least mean square (LMS).

The filter unit 23 derives an optimum tap coefficient of the filter 62 that minimizes the error “e” for each combination of the light intensity “Pᵢₙ” of the input electric field waveform and the transmission distance “L”.

As described above, the linear change generation unit 63 performs the linear change processing on the input electric field waveform “Eᵢₙ”. The filter 62 derives the simulation signal “Eₒᵤₜ” of the output electric field waveform by performing the nonlinear change processing on the input electric field waveform “Eᵢₙ” subjected to the linear change processing by the linear change generation unit 63. The error rate estimation device 7b estimates an error rate of a received code sequence at the output terminal of the transmission line 130 (second communication device 120) on the basis of the simulation signal “Eₒᵤₜ” of the output electric field waveform.

Thus, even in a case where a transmission distance of an optical signal is less than a predetermined distance, it is possible to improve accuracy of estimating a bit error rate in a short time on the basis of a nonlinearly changed electric field waveform while improving a convergence characteristic of the least mean square in tap coefficient derivation processing.

### Third Embodiment

In a third embodiment, main differences from the second embodiment are as follows: an electric field estimation device includes a photoelectric conversion unit; a filter generation device includes a photoelectric conversion unit; and an error rate estimation device does not include a photoelectric conversion unit. In the third embodiment, the differences from the second embodiment will be mainly described.

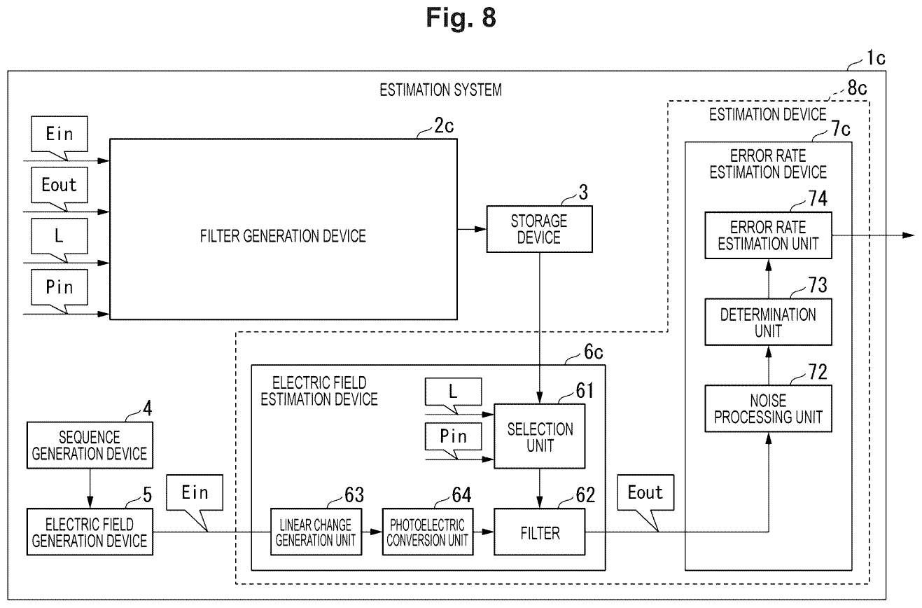

FIG. 8 shows a configuration example of an estimation system 1c in the third embodiment. The estimation system 1c includes a filter generation device 2c, the storage device 3, the sequence generation device 4, and the electric field generation device 5. The estimation system 1c includes an electric field estimation device 6c and an error rate estimation device 7c as an estimation device 8c.

The electric field estimation device 6c includes the selection unit 61, the filter 62, the linear change generation unit 63, and a photoelectric conversion unit 64. The error rate estimation device 7c includes the noise processing unit 72, the determination unit 73, and the error rate estimation unit 74.

At the estimation processing stage, the linear change generation unit 63 outputs the input electric field waveform “Eᵢₙ” subjected to the linear change processing to the photoelectric conversion unit 64. The photoelectric conversion unit 64 (detection unit) converts the input electric field waveform “Eᵢₙ” subjected to the linear change processing into an electrical signal (intensity waveform). The photoelectric conversion unit 64 outputs the electrical signal of the input electric field waveform “Eᵢₙ” subjected to the linear change processing to the filter 62.

At the estimation processing stage, the selection unit 61 sets, to the filter 62, a tap coefficient based on a characteristic of a nonlinear change in an electric field waveform of a transmitted optical signal. The filter 62 performs the nonlinear change processing on the electrical signal of the input electric field waveform “Eᵢₙ” subjected to the linear change processing by the linear change generation unit 63. The filter 62 outputs a simulation signal (electrical signal) of an output electric field waveform subjected to the nonlinear change processing to the noise processing unit 72.

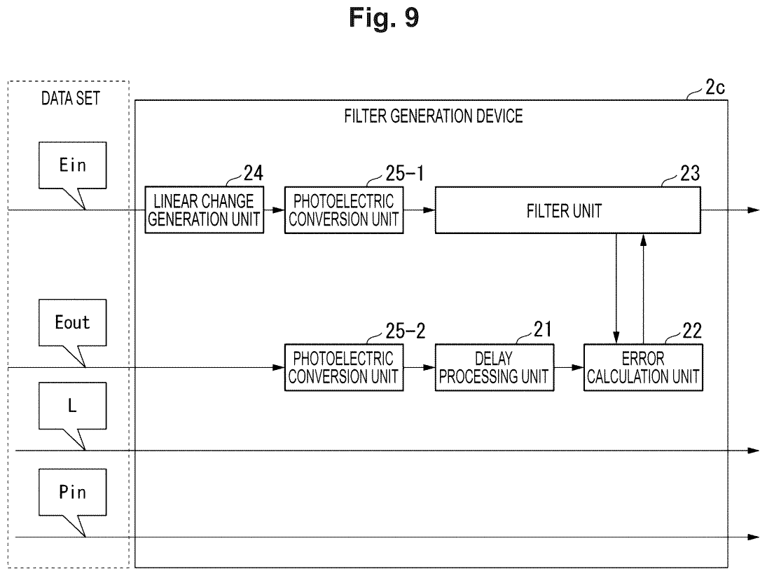

FIG. 9 shows a configuration example of the filter generation device 2c in the third embodiment. The filter generation device 2c includes the delay processing unit 21, the error calculation unit 22, the filter unit 23, the linear change generation unit 24, a photoelectric conversion unit 25-1, and a photoelectric conversion unit 25-2.

At a stage (lookup table deriving stage) before the estimation processing stage, the linear change generation unit 24 performs the linear change processing on the electric field waveform on the basis of a linear change derivation result. The linear change generation unit 24 outputs the input electric field waveform “Eᵢₙ” subjected to the linear change processing to the photoelectric conversion unit 25-1.

The photoelectric conversion unit 25-1 converts the input electric field waveform “Eᵢₙ” subjected to the linear change processing into an electrical signal. The photoelectric conversion unit 25-1 outputs the electrical signal of the input electric field waveform “Eᵢₙ” subjected to the linear change processing to the filter unit 23. The photoelectric conversion unit 25-2 converts the output electric field waveform “Eₒᵤₜ” into an electrical signal. The photoelectric conversion unit 25-2 outputs the electrical signal having the output electric field waveform “Eₒᵤₜ” to the delay processing unit 21.

The delay processing unit 21 acquires the electrical signal of the output electric field waveform “Eₒᵤₜ” from the photoelectric conversion unit 25-2. In a case where a predetermined time has elapsed from an acquisition time of the electrical signal of the output electric field waveform “Eₒᵤₜ”, the delay processing unit outputs the electrical signal of the output electric field waveform “Eₒᵤₜ” to the error calculation unit 22.

The filter unit 23 acquires the electrical signal of the input electric field waveform “Eᵢₙ” subjected to the linear change processing from the photoelectric conversion unit 25-1. The filter unit 23 acquires the error “e” from the error calculation unit 22. The filter unit 23 derives an appropriate tap coefficient of the filter 62 for each combination of the light intensity “Pᵢₙ” of the input electric field waveform and the transmission distance “L”.

As described above, the linear change generation unit 63 performs the linear change processing on the input electric field waveform “Eᵢₙ”. The photoelectric conversion unit 64 converts the input electric field waveform “Eᵢₙ” subjected to the linear change processing into an electrical signal. The photoelectric conversion unit 64 outputs the electrical signal of the input electric field waveform “Eᵢₙ” subjected to the linear change processing to the filter 62. The filter 62 derives the simulation signal “Eₒᵤₜ” of the output electric field waveform by performing the nonlinear change processing on the electrical signal of the input electric field waveform “Eᵢₙ” subjected to the linear change processing. The error rate estimation device 7c estimates an error rate of a code sequence at the output terminal of the transmission line 130 (second communication device 120) on the basis of the simulation signal “Eₒᵤₜ” of the output electric field waveform.

Thus, even in a case where a transmission distance of an optical signal is less than a predetermined distance, it is possible to improve accuracy of estimating a bit error rate in a short time on the basis of a nonlinearly changed electric field waveform.

### (Hardware Configuration)

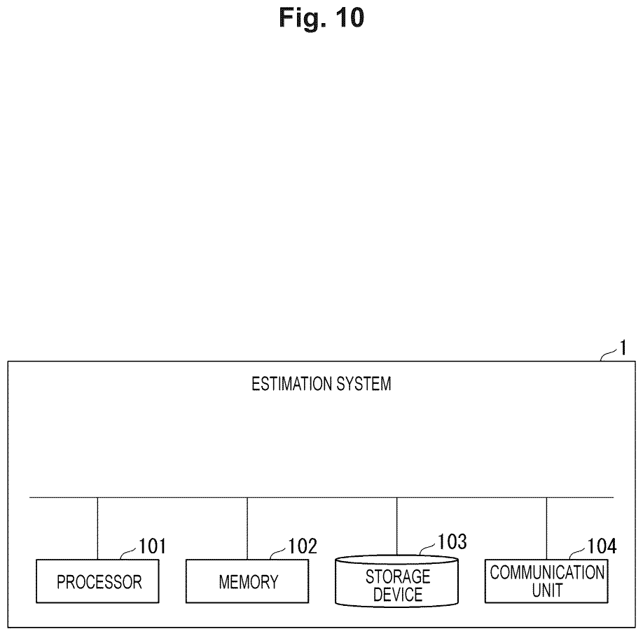

FIG. 10 shows a hardware configuration example of the estimation system in each embodiment. The estimation system 1 of FIG. 10 corresponds to the estimation system 1a in the first embodiment, the estimation system 1b in the second embodiment, and the estimation system 1c in the third embodiment.

The estimation system 1 is implemented as software by a processor 101 such as a central processing unit (CPU) executing a program stored in a storage device 103 including a nonvolatile recording medium (non-transitory recording medium) and a memory 102. The program may be recorded in a computer-readable recording medium. The computer-readable recording medium is, for example, a portable medium such as a flexible disk, a magneto-optical disc, a read only memory (ROM), or a compact disc read only memory (CD-ROM) or a non-transitory recording medium such as a storage device such as a hard disk or a solid state drive (SSD) built in a computer system. A communication unit 104 performs predetermined communication processing.

The estimation system 1 may be implemented by using hardware (accelerator) including an electronic circuit or circuitry using, for example, a large scale integrated circuit (LSI), an application specific integrated circuit (ASIC), a programmable logic device (PLD), or a field programmable gate array (FPGA).

Although the embodiments of the present invention have been described in detail with reference to the drawings, specific configurations are not limited to the embodiments and include design and the like within the scope of the present invention.

### INDUSTRIAL APPLICABILITY

The present invention can be applied to an optical communication system.

### REFERENCE SIGNS LIST

1, 1a, 1b, 1c Estimation system
2a, 2b, 2c Filter generation device
3 Storage device
4 Sequence generation device
5 Electric field generation device
6a, 6b, 6c Electric field estimation device
7a, 7b, 7c Error rate estimation device
8a, 8b, 8c Estimation device
21 Delay processing unit
22 Error calculation unit
23 Filter unit
24 Linear change generation unit
25 Photoelectric conversion unit
61 Selection unit
62 Filter
63 Linear change generation unit
64 Photoelectric conversion unit
71 Photoelectric conversion unit
72 Noise processing unit
73 Determination unit
74 Error rate estimation unit
100 Optical communication system
101 Processor
102 Memory
103 Storage device
104 Communication unit
110 First communication device
120 Second communication device
130 Transmission line

1. An estimation device comprising:
a processor; and
a storage medium having computer program instructions stored thereon, when executed by the processor, perform to:
estimates a simulation signal of an output electric field waveform at an output terminal of a transmission line by using a filter of a tap coefficient generated for each combination of a light intensity of a first input electric field waveform at an input terminal of the transmission line and a transmission distance on the basis of the first input electric field waveform and the output electric field waveform and a generated second input electric field waveform; and
estimates an error rate of a code sequence at the output terminal of the transmission line on the basis of the simulation signal of the output electric field waveform.

2. The estimation device according to claim 1, wherein, of linear waveform distortion and nonlinear waveform distortion, the filter applies at least the nonlinear waveform distortion to the simulation signal of the output electric field waveform by using the tap coefficient.

3. The estimation device according to claim 1, wherein the simulation signal of the output electric field waveform is an electric field waveform or an intensity waveform.

4. (canceled)

5. (canceled)

6. An estimation method performed by an estimation device, the estimation method comprising:
a step of estimating a simulation signal of an output electric field waveform at an output terminal of a transmission line by using a filter of a tap coefficient generated for each combination of a light intensity of a first input electric field waveform at an input terminal of the transmission line and a transmission distance on the basis of the first input electric field waveform and the output electric field waveform and a generated second input electric field waveform; and
a step of estimating an error rate of a code sequence at the output terminal of the transmission line on the basis of the simulation signal of the output electric field waveform.

7. A filter generation method performed by a filter generation device, the filter generation method comprising
a step of generating a tap coefficient of a filter for each combination of a light intensity of an input electric field waveform at an input terminal of a transmission line and a transmission distance so as to reduce a difference between a shape of a first output electric field waveform at an output terminal of the transmission line and a shape of a second output electric field waveform output from the filter.
